(19) United States
(12) Patent Application Publication
(10) Pub. No.: US 2025/0369100 A1
(43) Pub. Date: Dec. 4, 2025

(54) A BARRIER DEPOSIT WITHIN A SUBSTRATE

(71) Applicant: Beneq Oy, Espoo (FI)

(72) Inventor: Sami Sneck, Espoo (FI)

(21) Appl. No.: 18/875,858

(22) PCT Filed: Jun. 19, 2023
(86) PCT No.: PCT/FI2023/050362

§ 371 Date: Dec. 17, 2024

(30) Foreign Application Priority Data
Jun. 29, 2022 (FI) 20225589

(51) Int. Cl. C23C 16/04; C23C 16/455

(52) U.S. Cl. CPC C23C 16/045; C23C 16/45553; C23C 16/45555

(57) ABSTRACT

A method for forming a barrier deposit within a substrate comprising defects is disclosed. The method comprises introducing the substrate into a reaction space, wherein: —the substrate contains water and/or is exposed to water, and simultaneously the substrate is exposed to a first chemical, wherein the first chemical is configured to react with the water; and—the substrate is subjected to a diffusion treatment for allowing the water and the first chemical to diffuse into the defects of the substrate in order to react with each other within the substrate to form a barrier deposit within the substrate clogging the defects in the substrate. Further is disclosed a substrate comprising a barrier deposit within the substrate and the use of the method.

### PRIOR RELATED APPLICATIONS

The present application is a national entry of pct application no. PCT/FI2023/050362, filed on Jun. 19, 2023, which claims priority under the Paris Convention to Finnish Application No. FI 20225589, filed on Jun. 29, 2022, the entire contents of such prior applications are incorporated by reference herein.

### FIELD OF THE DISCLOSURE

The present disclosure relates to a method for forming a barrier deposit within a substrate comprising defects. Further, the present disclosure relates to a substrate comprising a barrier deposit within the substrate. The present disclosure further relates to the use of the method.

### BACKGROUND OF THE DISCLOSURE

Protecting different kinds of substrates from the effects of the surrounding environment has typically been carried out by depositing a barrier coating on the substrate. Such coating techniques may include atomic layer deposition (ALD), chemical vapor deposition (CVD), and physical vapor deposition (PVD). Such barrier coating may however contain defects such as pinholes through which e.g. moisture from the surrounding environment may penetrate into and through the barrier coating to the substrate affecting for example the lifetime of the substrate. A manner to solve such problem has been to produce several layers of the barrier material one upon the other However, there still remains a need to find a way to protect the substrates for different applications.

### SUMMARY OF THE DISCLOSURE

A method for forming a barrier deposit within a substrate comprising defects is disclosed. The method comprises introducing the substrate into a reaction space, wherein
the substrate contains water and/or is exposed to water, and simultaneously the substrate is exposed to a first chemical, wherein the first chemical is configured to react with the water; and
the substrate is subjected to a diffusion treatment for allowing the water and the first chemical to diffuse into the defects of the substrate in order to react with each other within the substrate to form a barrier deposit within the substrate clogging the defects in the substrate.

Further is disclosed a substrate comprising a barrier deposit within the substrate clogging defects present in the substrate, wherein the barrier deposit is obtainable by the method as disclosed in the current specification.

Further is disclosed a substrate comprising a barrier deposit within the substrate clogging defects present in the substrate, wherein the barrier deposit comprises or consists of a metal oxide, a metal carbonate, or a metal hydroxide.

Further is disclosed the use of the method as defined in the current specification for reducing electrical conductivity of the substrate.

Further is disclosed the use of the method as defined in the current specification for minimizing diffusion of molecules from the surrounding environment of the substrate into and/or through the substrate.

### BRIEF DESCRIPTION OF THE DRAWINGS

The accompanying drawings, which are included to provide a further understanding of the method and the substrate and constitute a part of this specification, illustrate embodiments and together with the description help to explain the principles of the above. In the drawings:

FIG. 1 illustrates a method for forming a barrier deposit within a substrate according to one embodiment,

FIG. 2 illustrates a method for forming a barrier deposit within a substrate according to another embodiment; and

### DETAILED DESCRIPTION

A method for forming a barrier deposit within a substrate comprising defects is disclosed. The method comprises introducing the substrate into a reaction space, wherein
the substrate contains water and/or is exposed to water, and simultaneously the substrate is exposed to a first chemical, wherein the first chemical is configured to react with the water; and
the substrate is subjected to a diffusion treatment for allowing the water and the first chemical to diffuse into the defects of the substrate in order to react with each other within the substrate to form a barrier deposit within the substrate clogging the defects in the substrate.

Further is disclosed a substrate comprising a barrier deposit within the substrate clogging defects present in the substrate, wherein the barrier deposit is obtainable by the method as disclosed in the current specification.

Further is disclosed a substrate comprising a barrier deposit within the substrate clogging defects present in the substrate, wherein the barrier deposit comprises or consists of a metal oxide, a metal carbonate, or a metal hydroxide.

Further is disclosed the use of the method as defined in the current specification for reducing electrical conductivity of the substrate.

Further is disclosed the use of the method as defined in the current specification for minimizing diffusion of molecules from the surrounding environment of the substrate into and/or through the substrate.

By the expressions “defects” should be understood in this specification, unless otherwise stated, as referring to cracks, fissures, and/or pinholes that are present in the substrate. E.g. as a result of its production process, the substrate may comprise defects of different size and shape within the substrate. In one embodiment, at least some of the defects are surrounded by the material of the substrate. Such defects do not open through to the (top) surface of the substrate but lie within the substrate. In one embodiment, at least some of the defects in the substrate opens through to the surface of the substrate. In one embodiment, the barrier deposit at least partially fills the defects of the substrate such that the barrier deposit may confirm to the shape of the surface of the defects. In one embodiment, the barrier deposit fills and/or clogs essentially all of the defects of the substrate.

Different substrates, such as films or coatings are used in e.g. industry in many applications. A typical disadvantage is that such substrates, e.g. films with coating layers thereon, may include pinholes or other defects that limit their performance to a lower level than the intrinsic properties of an intact substrate. The inventor surprisingly found out a manner to clog such defects present in the substrate in order to improve the performance of the substrate. The inventor surprisingly found out that when the barrier deposit is formed within the substrate in the defects therein the barrier deposit is also mechanically protected by the substrate itself. This may beneficially reduce it to be worn off and thus prolonging the lifetime of the substrate.

The substrate to be treated may be formed in different manners and of different materials. In one embodiment, the substrate is formed of polymer, paper, ceramic, porous metal, porous glass, and/or wood. In one embodiment, the substrate comprises or consists of polymer, paper, ceramic, porous metal, porous glass, and/or wood.

In one embodiment, the substrate is formed of a barrier coating on a web formed of polymer, paper, or wood. I.e. the substrate may comprise or consist of a separate barrier coating formed on a film.

In one embodiment, the substrate is porous.

Typically barrier coatings deposited on substrates may contain defects such as pinholes through which e.g. moisture from the surrounding environment may penetrate into and through the barrier coating to the substrate. For example, the substrate may be a plastic film used in e.g. food processing industry. Such a plastic film may easily absorb moisture from the environment through its defects negatively affecting the product to be protected by the plastic film. The method as disclosed in the current specification has the added utility of clogging such defects. By the method as disclosed in the current specification such defects may be deposited with more coating material forming a barrier deposit.

The substrate may contain water. The substrate may contain water e.g. as a result of its productions process or since the substrate is made of a material that absorbs water from the surrounding or environment. The water may be present in the substrate as moisture.

The first chemical that is used in the method is to be a chemical able to react with water thus forming a barrier deposit within the defects in the substrate. In one embodiment, the first chemical is selected from a group consisting of metal halides, metal organics, or organometals. Also other chemicals used as precursors in e.g. atomic layer deposition (ALD) or chemical vapor deposition (CVD) to form solid material through gas phase reactions may be used as the first chemical. TiCl₄, SiCl₄, and SnCl₄, may be presented as examples of a metal halide. Ti(OEt)₄, Ti(OⁱPr)₄, and Cu(hfac)₂, may be presented as examples of a metal organic. AlMe₃, Ti(N(Me₂))₄, and MgCp₂, may be presented as examples of an organometal. However, depending on the material of the barrier deposit to be formed also other chemicals may be chosen within the knowledge of the person skilled in the art.

The barrier deposit may comprise or consist of a metal oxide, a metal carbonate, or a metal hydroxide. As examples only of such barrier deposits TiO₂, MgCO₃, and Al(OH)₃, respectively, may be mentioned.

In one embodiment, the substrate contains water or is exposed to water. In one embodiment, the substrate contains water and is exposed to water. In one embodiment, the substrate contains water. In one embodiment, the substrate is exposed to water.

In one embodiment, the substrate contains water and simultaneously the substrate is exposed to the first chemical. In one embodiment, the substrate is exposed to water, and simultaneously the substrate is exposed to the first chemical. In one embodiment, the substrate contains water and is exposed to water and simultaneously the substrate is exposed to the first chemical.

In the method, the substrate is simultaneously affected by water and the first chemical, or exposed thereto, such that these are diffused into the defects of the substrate and thus forming a barrier deposit therein e.g. through reactions taking place between water and the first chemical. When allowing the presence of both water and the first chemical at the same time in the reaction space, the reactions between the same are efficiently taking place.

The diffusion treatment may be carried out at the same time or simultaneously with exposing the substrate to the first chemical and optionally water. Alternatively, the substrate may firstly be exposed to the first chemical and optionally water, and thereafter subjected to the diffusion treatment.

By the term “diffusion treatment” is to be understood that water and first chemical are allowed to diffuse into the defects of the substrate such that they may react with each other within the substrate.

In one embodiment, the diffusion treatment is carried out at a temperature of 0-1000° C., or 20-600° C., or 40-400° C., or 60-300° C., or 80-200° C., or 100-150° C. The temperature used in the diffusion treatment may depend on the material of the substrate to be treated as well as on the first chemical. In one embodiment, the substrate comprises or consists of plastic and the diffusion treatment is carried out at a temperature of 0-300° C., or 20-200° C., or 40-100° C. In on embodiment, the substrate comprises or consists of ceramic or porous metal, and the diffusion treatment is carried out at a temperature of 0-1000° C., or 100-600° C., or 200-400° C. The used temperature may have the effect of promoting the reactions taking place between water and the first chemical. The reactions may be e.g. accelerated by the used temperature.

In one embodiment, the diffusion treatment is carried out by arranging a pressure difference between different sides of the substrate.

In one embodiment, the substrate comprises a first outer surface and a second outer surface, which is opposite to the first outer surface, and the diffusion treatment is carried out by arranging, in the reaction space, a different pressure on the side of the first outer surface of the substrate than on the side of the second outer surface of the substrate.

In one embodiment, the substrate comprises a first outer surface and a second outer surface, which is opposite to the first outer surface, and the diffusion treatment is carried out by arranging, in the reaction space, a different pressure on the side of the first outer surface of the substrate than on the side of the second outer surface of the substrate, wherein the pressure difference results in the diffusion of the water and the first chemical into the defects of the substrate.

The pressure may be higher on the side of the first outer surface of the substrate than on the side of the second outer surface of the substrate, or vise versa. The pressure difference has the added utility of resulting in the first chemical(s), and water where needed, to diffuse into the defects of the substrate, in order to react with each other.

In one embodiment, the pressure difference is 1-1000000 Pa, or 10-10000 Pa, or 100-1000 Pa. In one embodiment, the pressure on the side of one of the first surface and the second surface of the substrate is 1-1000000 Pa, or 100-200000 Pa, or 1000-110000 Pa, and the pressure on the side of the other of the first surface and the second surface is 1-110000 Pa, or 100-101325 Pa, or 1000-101325 Pa. In one embodiment, the pressure on the side of one of the first surface and the second surface of the substrate is 1-1000000 Pa, or 100-200000 Pa, or 1000-110000 Pa, and the pressure on the side of the other of the first surface and the second surface is 1-110000 Pa, or 100-101325 Pa, or 1000-101325 Pa, wherein the pressures are selected such that a pressure difference of 1-1000000 Pa, or 10-10000 Pa, or 100-1000 Pa, is achieved. The reactions taking place may be accelerated by modulating the used pressures or the pressure difference.

In one embodiment, the diffusion treatment is continued for 0.01-1000 minutes, or 0.1-100 minutes, or 1-10 minutes. The time period for how long the diffusion treatment is allowed to continue may depend on the amount and/or size of the defects present in the substrate and e.g. on how much of the barrier deposit is to be formed. In one embodiment, the thickness of the formed barrier deposit is 1-10000 nm, or 5-500 nm, or 20-100 nm. The thickness of the formed barrier deposit may be measured using scanning electron microscope from the cross section of the substrate with the barrier deposit. The diffusion treatment may also be repeated one or more times.

In one embodiment, the substrate comprises a first outer surface and a second outer surface, which is opposite to the first outer surface.

In one embodiment, the substrate comprises a first outer surface and a second outer surface, which is opposite to the first outer surface, and wherein one of the first surface and the second surface of the substrate is exposed to one of water and the first chemical, and the other of the first surface and the second surface is exposed to the other one of water and the first chemical.

In one embodiment, the substrate contains water and is separately exposed only to the first chemical. In one embodiment, the substrate contains water and is separately exposed only to the first chemical from the side of the first outer surface and/or the second outer surface. The substrate may contain water, such as moisture, as a result of its productions process and/or due to absorbing moisture from the surrounding environment e.g. during storage.

In one embodiment, the method comprises forming the barrier deposit within the substrate for minimizing diffusion of molecules from the surrounding environment of the substrate into and/or through the substrate.

In one embodiment, the method comprises forming the barrier deposit within the substrate for reducing the electrical conductivity of the substrate.

The method as disclosed in the current specification has the added utility of clogging defects present within a substrate whereby e.g. the lifetime of the substrate may be prolonged and the performance of the substrate may be increased.

Clogging the defects present withing the substrate has the added utility of the formed barrier deposit being mechanically protected by the substrate.

### EXAMPLES

Reference will now be made in detail to the described embodiments, examples of which are illustrated in the accompanying drawings.

The description below discloses some embodiments in such a detail that a person skilled in the art is able to utilize the method based on the disclosure. Not all steps of the embodiments are discussed in detail, as many of the steps will be obvious for the person skilled in the art based on this specification.

For reasons of simplicity, item numbers will be maintained in the following exemplary embodiments in the case of repeating components.

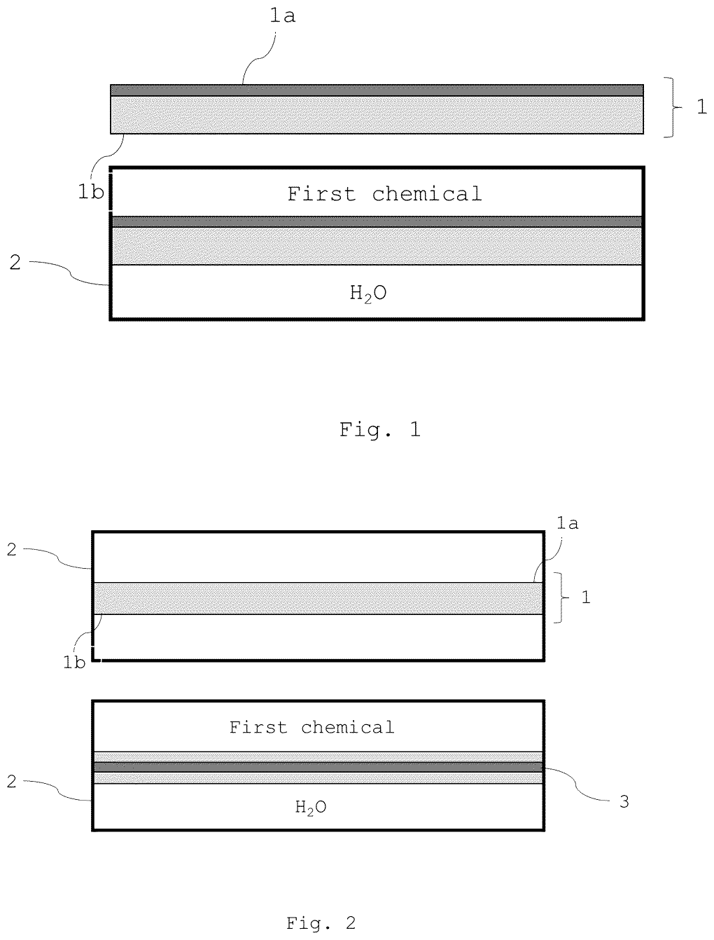

FIG. 1 illustrates how to form a barrier deposit within the substrate according to one embodiment described in this description. In this embodiment, the substrate 1 is formed of a barrier coating on a web formed of polymer. The substrate comprises a first outer surface 1a and a second outer surface 1b. The substrate 1 is inserted into a reaction space 2, wherein it is exposed to the first chemical from the side of the first outer surface 1a and simultaneously to water from the side of the second outer surface 1b. Subjecting the substrate to a diffusion treatment diffuses the first chemical and the water into the substrate and as a result a barrier deposit is formed in the defects present in the substrate.

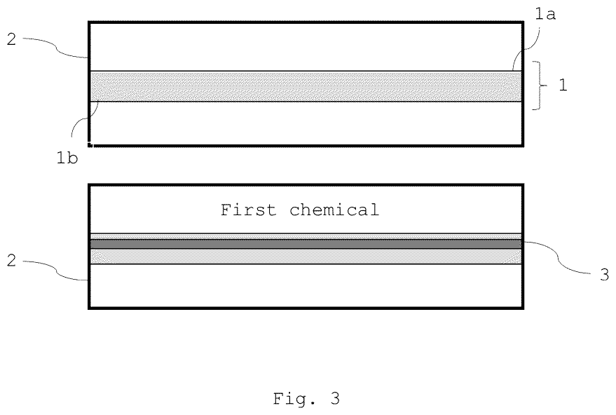

FIG. 2 illustrates how to form a barrier deposit within the substrate according to another embodiment described in this description. In this embodiment, the substrate is a dry polymer film. The substrate comprises a first outer surface 1a and a second outer surface 1b. The substrate 1 is inserted into a reaction space 2, wherein it is exposed to the first chemical from the side of the first outer surface 1a and simultaneously to water from the side of the second outer surface 1b. Subjecting the substrate to a diffusion treatment diffuses the first chemical and the water into the substrate and as a result a barrier deposit 3 is formed in the defects present in the substrate.

FIG. 3 illustrates how to form a barrier deposit within the substrate according to yet another embodiment described in this description. In this embodiment, the substrate is a polymer film containing moisture as a result of having absorbed the same from the surrounding environment. The substrate comprises a first outer surface 1a and a second outer surface 1b. The substrate 1 is inserted into a reaction space 2, wherein it is exposed to the first chemical from the side of the first outer surface 1a. The diffusion treatment is carried out by arranging a higher pressure on the side of the first outer surface and a lower pressure on the side of the second outer surface. The first chemical is diffused into the substrate as a result of the pressure difference between the first outer surface and the second outer surface. When the first chemical is diffused into the substrate it is contacted with the moisture that the substrate contains and is thus reacted with the moisture whereby a barrier deposit 3 is formed.

In FIGS. 1-3 the barrier deposit is presented in the form of a layer. However, the barrier deposit may be formed in the defects of the substrate only whereby no continuous layer is formed but separate deposits are formed in the defects.

### Example 1—Forming a Barrier Deposit within a Substrate

In this example a barrier deposit was formed within a substrate. As a substrate was used a molded polymer enclosure (polypropylene, 50×50×10 mm), with an electronic device inside the enclosure. The polymer enclosure contained some moisture (H₂O) absorbed from the surrounding atmosphere. The polymer enclosure was placed in a reaction space, where it was exposed, from the side of the first outer surface, to a nitrogen environment with a saturated concentration of Al(Me)₃ at a temperature of 70° C. temperature for 60 minutes. During this Al(Me)₃ exposure, Al(Me)₃ was diffused into the polymer enclosure and met with H₂O present in the polymer enclosure at the surface of the polymer enclosure, and reacted. This resulted in the formation of an Al₂O₃ layer on the surface of the polymer part. Part of the Al(Me)₃ diffused into the “walls” of the polymer enclosure and reacted with moisture within the polymer enclosure, leading to formation of a Al₂O₃ barrier deposit within the polymer enclosure.

As the diffusion treatment was continued, the formed barrier deposit became more and more dense. Diffusion of Al(Me)₃ through the polymer enclosure then mainly happened through the remaining defects in the barrier deposit. This led to more reactions around the defects, causing the defects to be blocked by Al₂O₃.

Thus, a polymer enclosure with an Al₂O₃ barrier deposit that extended from the outer surface of the enclosure to the opposite surface of the polymer enclosure.

### Example 2—Forming a Barrier Deposit within a Substrate

In this example a barrier deposit was formed within a substrate. As a substrate was used a pre-dried 1200 mm wide polymer film (polyethylene, thickness 50 μm). The polymer film was continuously moved through a reaction space, where the side of the first outer surface of the polymer film was exposed to a nitrogen environment saturated with TiCl₄ at 70° C. and the side of the second outer surface was simultaneously exposed to air environment comprising water vapor (90% RH at 70° C.). The reaction space was one meter (1 m) long and the polymer film was moving through the reaction space from one end to the other at 1 m/min line speed. During the 1 minute that a section of the film travelled through the reaction space, TiCl₄ and H₂O were diffusing into the film from opposite directions or sides of the polymer film and met inside the polymer film and reacted with each other. This resulted in the formation of a TiO₂ barrier deposit within the polymer film.

As the diffusion treatment was continued, the formed barrier deposit became more and more dense. Diffusion of TiCl₄ and H₂O through the polymer film then happen mainly happened through the remaining defects in the barrier deposit. This led to more reactions around the defects, causing the defects to be blocked by TiO₂.

Thus, a polymer film with a TiO₂ barrier deposit within the polymer film was formed.

### Example 3—Forming a Barrier Deposit within a Substrate

In this example a barrier deposit was formed within a substrate. As a substrate was used a 100×100 mm polymer film (PET, thickness 100 μm) with moisture absorbed from the surrounding atmosphere. The polymer film was placed in a reaction space, where the side of the first outer surface of the polymer film was connected to a vacuum pump and the absolute pressure on this side of the polymer film was maintained at a pressure of 3000+/−100 Pa. The side of the second outer surface of the polymer film was connected to another vacuum pump and was maintained at a pressure of 1000+/−100 Pa. Reaction space with the polymer film was maintained at a temperature of 100° C. A steady flow of 100 sccm of Al(Me)₃ vapor was subjected on the side of the first outer surface of polymer film for 10 minutes. During this Al(Me)₃ exposure, Al(Me)₃ diffused into the polymer film and reacted with the moisture within the polymer film. This resulted in the formation of a Al₂O₃ barrier deposit within the polymer film.

As the diffusion treatment was continued, the formed barrier deposit became more and more dense. Diffusion of Al(Me)₃ through the polymer film then mainly happened through the remaining defects in the barrier deposit. This led to more reactions around the defects, causing the defects to be blocked by Al₂O₃.

Thus, a polymer film with an Al₂O₃ barrier deposit within the polymer film was formed.

It is obvious to a person skilled in the art that with the advancement of technology, the basic idea may be implemented in various ways. The embodiments are thus not limited to the examples described above; instead they may vary within the scope of the claims.

The embodiments described hereinbefore may be used in any combination with each other. Several of the embodiments may be combined together to form a further embodiment. A method, a substrate, or a use as disclosed herein, may comprise at least one of the embodiments described hereinbefore. It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items. The term “comprising” is used in this specification to mean including the feature(s) or act(s) followed thereafter, without excluding the presence of one or more additional features or acts.

1. A method for forming a barrier deposit within a substrate comprising defects, wherein the method comprises introducing the substrate into a reaction space, wherein:
the substrate contains water and/or is exposed to water, and simultaneously the substrate is exposed to a first chemical, wherein the first chemical is configured to react with the water; and
the substrate is subjected to a diffusion treatment for allowing the water and the first chemical to diffuse into the defects of the substrate in order to react with each other within the substrate to form a barrier deposit within the substrate clogging the defects in the substrate.

2. The method of claim 1, wherein the first chemical is selected from a group consisting of metal halides, metal organics, or organometals.

3. The method of claim 1, wherein the diffusion treatment is carried out at a temperature of 0-1000° C., or 20-600° C., or 40-400° C., or 60-300° C., or 80-200° C., or 100-150° C.

4. The method of claim 1, wherein the substrate comprises a first outer surface and a second outer surface, which is opposite to the first outer surface, and the diffusion treatment is carried out by arranging, in the reaction space, a different pressure on the side of the first outer surface of the substrate than on the side of the second outer surface of the substrate, wherein the pressure difference results in the diffusion of the water and the first chemical into the defects of the substrate.

5. The method of claim 1, wherein the diffusion treatment is continued for 0.01-1000 minutes, or 0.1-100 minutes, or 1-10 minutes.

6. The method of claim 1, wherein the substrate is formed of polymer, paper, ceramic, porous metal, porous glass, and/or wood.

7. The method of claim 1, wherein the substrate is formed of a barrier coating on a web formed of polymer, paper, and/or wood.

8. The method of claim 1, wherein the substrate is porous.

9. The method of claim 1, wherein the thickness of the formed barrier deposit is 1-10000 nm, or 5-500 nm, or 20-100 nm.

10. The method of claim 1, wherein the substrate comprises a first outer surface and a second outer surface, which is opposite to the first outer surface, and wherein one of the first surface and the second surface of the substrate is exposed to one of water and the first chemical, and the other of the first surface and the second surface is exposed to the other one of water and the first chemical.

11. The method of claim 1, wherein the method comprises forming the barrier deposit within the substrate for minimizing diffusion of molecules from the surrounding environment of the substrate into and/or through the substrate.

12. The method of claim 1, wherein the method comprises forming the barrier deposit within the substrate for reducing the electrical conductivity of the substrate.

13. A substrate comprising a barrier deposit within the substrate clogging defects present in the substrate, wherein the barrier deposit is obtainable by the method of claim 1.

14. A substrate comprising a barrier deposit within the substrate clogging defects present in the substrate, wherein the barrier deposit comprises or consists of a metal oxide, a metal carbonate, or a metal hydroxide.

15. Use of the method as defined in claim 1 for reducing electrical conductivity of the substrate.

16. The use of the method as defined in claim 1 for minimizing diffusion of molecules from the surrounding environment of the substrate into and/or through the substrate.
